(19) United States
(12) Patent Application Publication
(10) Pub. No.: US 2025/0194262 A1
(43) Pub. Date: Jun. 12, 2025

(54) ELECTROSTATIC DISCHARGE PROTECTION SYSTEM OF MICRO DEVICE

(71) Applicant: Jade Bird Display (Shanghai) Limited, Shanghai (CN)

(72) Inventors: Chunming LI, Shanghai (CN); Hongyun LIU, Shanghai (CN); Jing JU, Shanghai (CN); Qiming LI, Shanghai (CN)

(73) Assignee: Jade Bird Display (Shanghai) Limited, Pudong New Area, Shanghai (CN)

(21) Appl. No.: 18/837,223

(22) PCT Filed: Feb. 17, 2022
(86) PCT No.: PCT/CN2022/076575

§ 371 Date: Aug. 9, 2024

(51) Int. Cl. H10D 89/60; G09G 3/32

(52) U.S. Cl. CPC H10D 89/814; G09G 3/32; G09G 2330/04

(57) ABSTRACT

An electrostatic discharge (ESD) protection system of a micro device is disclosed. The ESD protection system comprises: a pixel driver circuit, electrically connected to at least one micro LED pixel for controlling the turning-on or off of the micro LED pixel, and a first ESD protective unit, electrically connected to a first level voltage (Vdd) and the second level voltage (Vcom). In some embodiments, the micro LED pixel is electrically connected to a second level voltage (Vcom). The ESD protection system can protect the micro LED pixel from being damaged by the electrostatic discharge. Various embodiments include an ESD protection system of a display panel with a micro-LED pixel array.

### TECHNICAL FIELD

The present disclosure relates generally to display devices and technology, and more particularly, to an electrostatic discharge protection system of a micro device.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

The electrostatic discharge (ESD) is one of the most prevalent threats to the reliability of electronic components. An ESD-related event happens when a finite amount of charge is transferred from one object to another, such as, from a human body to a micro device. This process would result in a very high current passing through the micro device within a very short period of time. In fact, more than 35% of chip damages can be attributed to an ESD-related event. Common failures from ESD are contact damage, current leakage, short circuits, gate oxide rupture, and burnout, etc. ESD failures are not predictable or easy to diagnose after they occur.

In addition, designing on-chip ESD structures to protect integrated circuits against the ESD stresses is a high priority task in the semiconductor industry. The continuing advancement in metal oxide semiconductor and other processing technologies makes ESD-induced failures even more prominent. In fact, many semiconductor companies worldwide are having difficulties in meeting the increasingly stringent ESD protection requirements for various electronics applications, and one can predict with certainty that the availability of effective and robust ESD protection solutions will become a critical and essential factor to the well-being and commercialization of the electronic industry.

Furthermore, micro lighting-emitting diode (LED) panel become extensively studied in the world. However, the micro LED is lack of ESD protection, which will result in damages in the micro LED panel, and would also limit its implementation and reliability.

### SUMMARY

There is a need for improved display designs that improve upon, and help to address the shortcomings of conventional display systems, such as those described above. In particular, there is a need for display panels with improved stability and reliability with better images.

In some embodiments, integrated circuit (IC) chips need protection against ESD at all pins of the packaged device. The ESD clamp is ideally in a high impedance state with tolerable capacitive load and triggers only when an ESD pulse is detected, thereby protecting an input/output (I/O) circuit. With the occurrence of an ESD pulse on the IC pad, the protection device clamps a major portion of the ESD current energy to the ground bus. The clamp device needs to be fully compatible with the I/O function.

Various embodiments include a display panel with integrated micro-LED array. The display panel typically includes an array of pixel light sources (e.g., LEDs, OLEDs) electrically coupled to corresponding pixel driver circuits (e.g., FETs). The micro LED panel comprises an IC back plane and a micro LED array electrically formed on the IC back plane.

In some embodiments, the present disclosure providesan ESD protection system for a micro device, especially for the micro LED panel, to solve the problem that the micro LED panel is always damaged by the outside electrostatic discharge.

To achieve the above objectives, some exemplary embodiments of the present disclosure provide an electrostatic discharge (ESD) protection system of a micro device, comprising: a pixel driver circuit, electrically connected to at least one micro LED pixel for controlling turning-on or off of the micro LED pixel, wherein, the micro LED pixel is electrically connected to a second level voltage (Vcom); and, a first ESD protective unit, electrically connected to a first level voltage (Vdd) and the second level voltage (Vcom).

In some exemplary embodiments or any combination of exemplary embodiments of the ESD protection system of the micro device, a cathode of the micro LED pixel is connected to the second level voltage (Vcom).

In some exemplary embodiments or any combination of exemplary embodiments of the ESD protection system of the micro device, the first ESD protective unit is connected to a fourth level voltage (Vss) and the second level voltage (Vcom).

In some exemplary embodiments or any combination of exemplary embodiments of the ESD protection system of the micro device, the fourth level voltage (Vss) is larger than the second level voltage (Vcom) and the first level voltage (Vdd) is larger than the fourth level voltage (Vss).

In some exemplary embodiments or any combination of exemplary embodiments of the ESD protection system of the micro device, the first level voltage (Vdd) is a positive voltage, the fourth level voltage (Vss) is Zero, and the second level voltage (Vcom) is a negative voltage.

In some exemplary embodiments or any combination of exemplary embodiments of the ESD protection system of the micro device, the first ESD protective unit comprises a power ESD clamp.

In some exemplary embodiments or any combination of exemplary embodiments of the ESD protection system of the micro device, the first ESD protective unit comprises a MOS transistor, a gate of the first ESD protective unit is connected to a source of the first ESD protective unit and the second level voltage (Vcom), the drain of the first ESD protective unit is connected to the first level voltage (Vdd), and, the first ESD protective unit has a parasitic on the MOS transistor.

In some exemplary embodiments or any combination of exemplary embodiments of the ESD protection system of the micro device, the MOS transistor is an NMOS.

In some exemplary embodiments or any combination of exemplary embodiments of the ESD protection system of the micro device, the first ESD protective unit comprises:
a first type semiconductor substrate;
a first type well region, formed in the first type semiconductor substrate;
a second type well, formed around the first type well region;
a second type deep well, formed at bottom of the second type well and at bottom of the first type well region;
a second type source, formed in the first type well region;
a second type drain, formed in the first type well region;
a first implanted region, formed beside the second type drain;
a gate, formed on the first type well region between the second type source and the second type drain and connected to the second type source and the first implanted region; and,
a second implanted region, formed beside the second type well.

In some exemplary embodiments or any combination of exemplary embodiments of the ESD protection system of the micro device, the first type is P type and the second type is N type, the first implanted region is a first P+ implanted region, and the second implanted region is a second P+ implanted region.

In some exemplary embodiments or any combination of exemplary embodiments of the ESD protection system of the micro device, the second type well and the second type drain are connected to the first level voltage (Vdd), the second implanted region is connected to the fourth level voltage (Vss), and the first implanted region, the second type source and the gate are connected to the second level voltage (Vcom).

In some exemplary embodiments or any combination of exemplary embodiments of the ESD protection system of the micro device, the at least one micro LED pixel is a micro LED pixels array, and the pixel driver circuit controls turning-on or turning-off of each of the micro LED pixels in the micro LED pixel array.

In some exemplary embodiments or any combination of exemplary embodiments of the ESD protection system of the micro device, the first ESD protective unit is connected to each of the micro LED pixels.

In some exemplary embodiments or any combination of exemplary embodiments of the ESD protection system of the micro device, the micro pixel driver circuit is connected to the first level voltage (Vdd) and the micro LED pixel.

In some exemplary embodiments or any combination of exemplary embodiments of the ESD protection system of the micro device, the system further comprises a second ESD protective unit, and the second ESD protective unit is connected to the first level voltage (Vdd) and a fourth level voltage (Vss).

In some exemplary embodiments or any combination of exemplary embodiments of the ESD protection system of the micro device, the first ESD protective unit and the second ESD protective unit are formed in a semiconductor substrate.

In some exemplary embodiments or any combination of exemplary embodiments of the ESD protection system of the micro device, the second ESD protective unit comprises multiple second ESD sub clamps, wherein a first end of each of the second ESD sub clamps is connected to the first level voltage (Vdd) and the pixel driver circuit, a second end of the each of the second ESD sub clamps is connected to the fourth level voltage (Vss), and, the second ESD sub clamps are connected to each other in parallel.

In some exemplary embodiments or any combination of exemplary embodiments of the ESD protection system of the micro device, the second ESD protective unit comprises a power rail ESD clamp.

In some exemplary embodiments or any combination of exemplary embodiments of the ESD protection system of the micro device, the micro device is selected from a micro inorganic LED device, or a micro organic LED device; and, the micro LED pixel is selected from an inorganic micro LED or an organic micro LED.

In some exemplary embodiments or any combination of exemplary embodiments of the ESD protection system of the micro device, the system further comprises a third ESD protective unit, a first end of the third ESD protective unit is connected to the first level voltage (Vdd) and a second end of the third ESD protective unit is connected to a fourth level voltage (Vss).

In some exemplary embodiments or any combination of exemplary embodiments of the ESD protection system of the micro device, the third ESD protective unit is connected to an Input/Output circuit.

In some exemplary embodiments or any combination of exemplary embodiments of the ESD protection system of the micro device, the third ESD protective unit comprises at least two third ESD sub clamps, and, the third ESD sub clamps are connected to each other in series.

In some exemplary embodiments or any combination of exemplary embodiments of the ESD protection system of the micro device, a first end of the micro pixel driver circuit is connected to a third level voltage (Vdd″), and a second end of the micro pixel driver circuit is connected to the micro LED pixel.

In some exemplary embodiments or any combination of exemplary embodiments of the ESD protection system of the micro device, the system further comprises a fourth ESD protective unit, and, a first end of the fourth ESD protective unit is connected to a third level voltage (Vdd″) and a second end of the fourth ESD protective unit is connected to a fourth level voltage (Vss).

In some exemplary embodiments or any combination of exemplary embodiments of the ESD protection system of the micro device, the fourth level voltage (Vss) is less than the third level voltage (Vdd″).

In some exemplary embodiments or any combination of exemplary embodiments of the ESD protection system of the micro device, the pixel driver circuit comprises at least one switch.

The design of the display devices and systems disclosed herein results in reduced ESD damages that improve the light emission efficiency, and overall performance of the display systems. Thus, implementation of the display systems with micro-lens arrays can better satisfy the display requirements for Augmented Reality (AR) and Virtual Reality (VR), heads-up displays (HUD), mobile device displays, wearable device displays, high-definition projectors, and automotive displays as compared with the use of conventional displays.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate of a light emitting structure, “down” means toward the substrate, and other directional terms such as top, bottom, above, below, under, beneath, etc. are interpreted accordingly.

FIG. 1 illustrates a schematic block diagram of an electrostatic discharge (ESD) protection system for a micro display, according to some embodiments.

FIG. 2 illustrates a circuit diagram of the ESD protection system for a micro display, according to some embodiments.

FIG. 3 illustrates a circuit diagram of an ESD protection unit, according to some embodiments.

FIG. 4 illustrates a cross-sectional view of the ESD protective unit, according to some embodiments.

FIG. 5 illustrates a circuit diagram of an ESD protection system for a micro display, according to some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

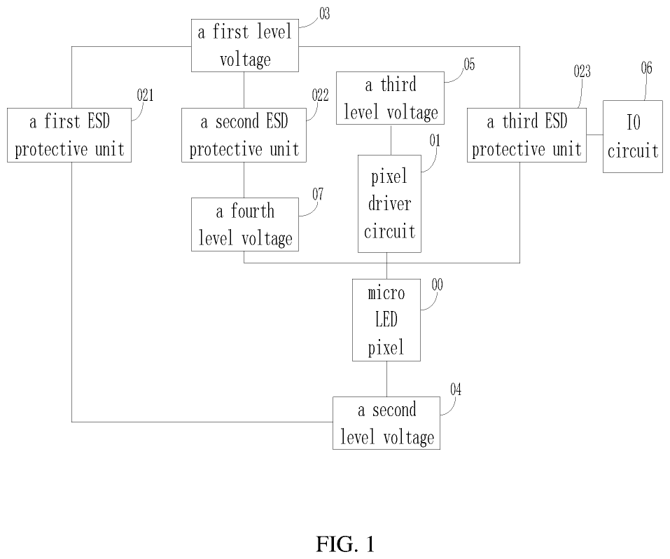

As discussed above, to resolve the problem in the related technologies, an ESD protection system of a micro device is provided in some embodiments of the present disclosure. FIG. 1 illustrates a schematic block diagram of an electrostatic discharge (ESD) protection system for a micro display, according to some embodiments.

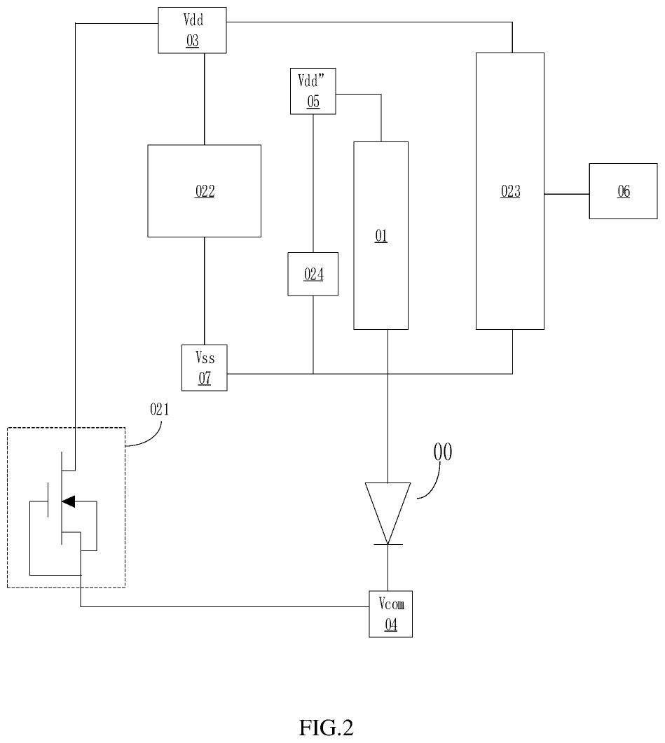

FIG. 2 illustrates a circuit diagram of the ESD protection system for a micro display, according to some embodiments.

Referring to FIG. 1 and FIG. 2, the ESD protection system of a micro device includes a pixel driver circuit 01 and a first ESD protective unit 021. The pixel driver circuit 01 is electrically connected to at least a micro LED pixel 00 for controlling the turning-on or off of the at least one micro LED pixel 00. Herein, the micro LED pixel 00 is further electrically connected to a second level voltage 04 (Vcom). The first ESD protective unit 021 is electrically connected to a first level voltage 03 (Vdd) and the second level voltage 04 (Vcom). One end of the micro pixel driver circuit 01 is connected to a third level voltage 05 (Vdd″), and another end of the micro pixel driver circuit 01 is connected to the micro LED pixel 00. In another embodiment, one end of the micro pixel driver circuit 01 is connected to a first level voltage 03 (Vdd), and another end of the micro pixel driver circuit 01 is connected to the micro LED pixel 00.

FIG. 5 illustrates a circuit diagram of an ESD protection system for a micro display, according to some embodiments. Referring to FIG. 5 and FIGS. 1 to 2, the ESD protection system in FIG. 1 further comprises a second ESD protective unit 022 and a third ESD protective unit 023. One end of the second ESD protective unit 021 is connected to the first level voltage 03 (Vdd) and the other end of the second ESD protective unit 021 is connected to a fourth level voltage 07 (Vss). Additionally, one end of the third ESD protective unit 023 is connected to the first level voltage 03 (Vdd) and another end of the third ESD protective unit 023 is connected to a fourth level voltage 07 (Vss). Furthermore, the second ESD protective unit 023 comprises at least two second ESD sub clamps 0221, and 0222. Preferably, the second ESD sub clamps are connected to each other in parallel. Herein, one end of each of the second ESD sub clamps 0221, 0222 is connected to the first level voltage 03 (Vdd), and the other end of each of the second ESD sub clamps is connected to the fourth level voltage 07 (Vss).

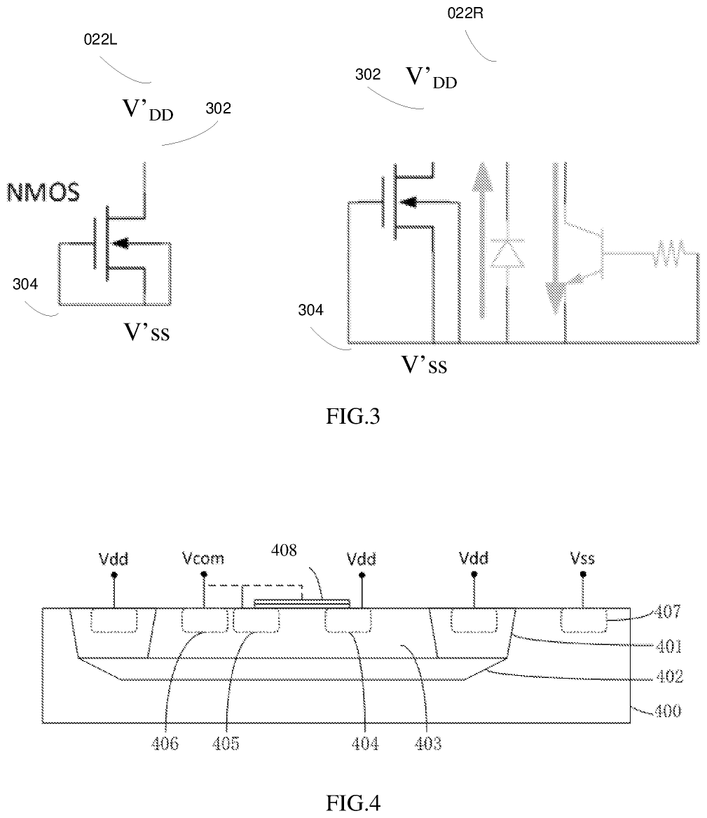

FIG. 3 illustrates a circuit diagram of an ESD protection unit, according to some embodiments. As shown in FIG. 3, the second ESD sub clamps 0221, and 0222 are formed by a grounded gate N-type metal-oxide-semiconductor (NMOS) ESD network, which can be referred in FIG. 3. FIG. 3 is an exemplary illustration of a power pin ESD network consisting of a grounded gate n-channel metal-oxide-semiconductor field-effect transistor (MOSFET) device. In some embodiments, the left structure 022L in FIG. 3 is a real power clamp and the right structure 022R in FIG. 3 is a diagram illustrating the principle of a power clamp ESD protection system. The grounded gate N-type metal-oxide-semiconductor (NMOS) ESD network, such as 022L, is a network for complementary metal-oxide-semiconductor (CMOS) technology. Typically, it is an n-channel MOSFET which has a MOSFET drain connected to a power pin 302 with V′DD, n-channel MOSFET also has its source and gate connected to the ground power rail 304. This circuit remains “off” in a normal operation. When the signal pin 302 exceeds the MOSFET snapback voltage, this circuit discharges to the V′SS power rail. In some examples, snapback voltage is a voltage applied to a transistor when avalanche breakdown or impact ionization in a transistor provides a sufficient base current to turn on the transistor. When the voltage of the signal pin 302 is below the ground potential, the MOSFET drain forwards biases to the p-well or p-substrate region, so as to achieve the purpose of electrostatic protection.

Referring to FIG. 5, an input/output (IO) circuit 06 is formed beside the pixel driver circuit 01 for receiving signals from an outside circuit. The third ESD protective unit 023 is connected to the IO circuit 06 for performing ESD protection to the IO circuit 06. The IO circuit 06 can be formed around the pixel driver circuit 01 or around the micro LED pixel 00 in another embodiment. The third ESD protective unit 023 comprises at least two third ESD sub clamps, for example, third ESD sub clamps 0231, and 0232, connected to each other in series. In some examples, the third ESD sub clamp 0231 is a PMOS and the third ESD sub clamp 0232 is an NMOS. One end of one third ESD sub clamp 0231 is connected to the first level voltage 03 (Vdd), the other end of the third ESD sub clamp 0231 is connected to another third ESD sub clamp 0232, and the third ESD sub clamp 0232 is connected to the fourth level voltage 07 (Vss). Furthermore, the gate and the source of the third ESD sub clamp 0231 is connected to the first level voltage 03 (Vdd), the drain of the third ESD sub clamp 0231 is connected to the source of the third ESD sub clamp 0232, the gate and the drain of the third ESD sub clamp 0232 is connected to the fourth level voltage 07 (Vss). The IO circuit 06 is connected to the drain of the third ESD sub clamp 0231 and the source of the third ESD sub clamp 0232.

Preferably, in some embodiments, the first level voltage 03 (Vdd) is larger than the second level voltage 04 (Vcom). The first level voltage 03 (Vdd) is larger than the third level voltage 05 (Vdd″). The fourth level voltage 07 (Vss) is larger than the second level voltage 04 (Vcom). And, the first level voltage 03 (Vdd) is larger than the fourth level voltage 07 (Vss). Because the micro LED pixel 00 can work under a high voltage value, the second level voltage 04 (Vcom) is a negative voltage, being applied onto the micro LED pixel 00. In some embodiments, preferably, the first level voltage 03 (Vdd) is a positive voltage, the third level voltage 05 (Vdd″) is a positive voltage and the fourth level voltage 07 (Vss) is Zero. For example, the voltage of the Vdd can be 1 V to 3 V, the voltage of the Vdd″ can be 1 V to 2 V, the voltage of the Vss can be 0 V and the voltage of the Vcom can be-5 V to 0V.

Referring to FIG. 2 and FIG. 5, in some embodiments, the ESD protection system further comprises a fourth ESD protective unit 024. One end of the fourth ESD protective unit 024 is connected to the third level voltage 05 (Vdd″) and the other end of the fourth ESD protective unit 024 is connected to a fourth level voltage 07 (Vss).

In some embodiments, the second ESD protective unit 022, the third ESD protective unit 023, the fourth ESD protective unit 024 are power rail ESD clamps, which can be referred to the description of FIG. 3.

Referring to FIG. 5 and FIG. 2, herein the first ESD protective unit 021 is a negative power ESD clamp. The first ESD protective unit 021 comprises a MOS transistor. Furthermore, the first ESD protective unit has a parasitic on the MOS transistor. The gate of the first ESD protective unit 021 is connected to the drain of the first ESD protective unit 021 and the second level voltage 04 (Vcom). The source of the first ESD protective unit 021 is connected to the first level voltage 03 (Vdd). The parasitic diode is parasitic on the MOS transistor. In some embodiments, when the second level voltage 04 (Vcom) is a negative voltage and the MOS transistor is preferably an NMOS. Herein, the cathode of the micro LED pixel 00 is connected to the second level voltage 04 (Vcom).

Referring to FIG. 5, the pixel driver circuit 01 comprises at least one switch, for example, switches 011, 012, and 013. Preferably, the switch 011, 012 and/or 013 is formed by a transistor. The switches 011, 012 and 013 are connected in series for realizing three levels of controlling the turning-on or turning-off of the micro LED pixel, so as to control the light emitting intensity and the light emitting time. For example, the switches 011, 012 and 013 are connected in series for controlling the turning-on or turning-off of the current of the micro pixel driver circuit 01, controlling the turning-on or turning-off of a PWM signal from an outside circuit, and controlling the turning-on or turning-off of a scanning signal from an outside circuit, respectively.

In some embodiments, the micro LED pixel 00 shown in FIG. 1 and FIG. 2 can be replaced by a micro LED pixel array, and, the pixel driver circuit 01 in FIG. 1 and FIG. 2 controls turning-on or turning-off of each of the micro LED pixels in the micro LED pixel array. Preferably, the first ESD protective unit 021 is connected to each of the micro LED pixels 00. In another embodiment, the first ESD protective unit 021 may comprise at least two first ESD sub clamps and each of the first ESD sub clamp is connected to the second level voltage 04 (Vcom) and connected to the first level voltage 03 (Vdd) respectively.

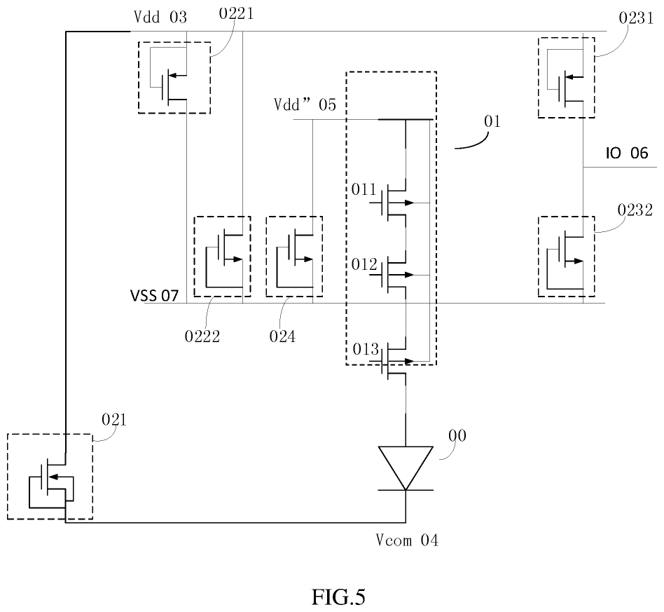

The first ESD protective unit, the second ESD protective unit, the third ESD protective unit and the fourth ESD protective unit are formed in a semiconductor substrate. FIG. 4 illustrates a cross-sectional view of the ESD protective unit according to some embodiments. FIG. 4 illustrates a cross-sectional structure of the ESD protective unit, for example, the first ESD protective unit 021. The semiconductor substrate 400 in FIG. 4 can be a first type semiconductor substrate such as silicon substrate. In some embodiments, the first ESD protective unit 021 includes: a first type well region 403, a second type well 401, a second type deep well 402, a second type drain 404, a second type source 405, a first implanted region 406, a gate 408 and a second implanted region 407. Furthermore, the first type well region 403 is formed in the first type semiconductor substrate 400. The second type well 401 is formed around the first type well region 403. The second type deep well 402 is formed at the bottom of the second type well 401 and at the bottom of the first type well region 403. The second type drain 404 is formed in the first type well region 403. The second type source 405 is formed in the first type well region 403. The first implanted region 406 is formed beside the second type source 405. The gate 408 is formed on the first type well region 403 between the second type drain 404 and the second type source 405 and connected to the second type source 405 and the first implanted region 406. The second implanted region 407 is formed beside the second type shallow well 401.

In some examples, the first type is P type and the second type is N type, which will not be limited to the scope of the present disclosure. As shown in FIG. 4, in some embodiments, an N deep well 402 is formed in the P type substrate 400 and an N well 401 is formed on and around the top edge of the N deep well 402, thereby forming a P type well region 403 surrounded by the N well 401. The N deep well 402 is formed at the bottom of the N well 401 and at the bottom of the P type well region 403. An N+ drain 404 is formed in the P type well region 403 and an N+ source 405 is formed in the P type well region 403. A gate 408 is formed on the P type well region 403 between the N+ drain 404 and the N+ source 405. The gate 408 is connected to the N+ source 405 and a first P+ implanted region 406. The first P+ implanted region 406 is formed in the P type well region 403 and close to the N+ source 405. A second P+ implanted region 407 is formed beside or around the N well 401. Furthermore, the N+ drain 404, the N well 401 are connected to the first level voltage 03 (Vdd). The second P+ implanted region 407 is connected to the fourth level voltage 07 (Vss). The N+ source 405, the first P+ implanted region 406 and the gate 408 are connected to the second level voltage 04 (Vcom), for example, Vcom 04 in FIG. 1 and FIG. 2. In some examples, the second P+ implanted region 407 is connected to the Vss, as a ground. In some embodiments, the gate 408 can be a gate structure comprising several material layers, such as a dielectric layer, spacer, etc. The gate 408 is a conventional gate structure, which can be understood by those skilled in the art and will not be described herein.

In some embodiments, the micro device, for example, as shown in FIG. 5, with one or more of the ESD protection units is selected from one of a micro inorganic LED device, and/or a micro organic LED device. In some embodiments, the micro LED pixel 00 is selected from inorganic micro LED or organic micro LED. For example, the micro device can be a micro display panel. The micro LED display panel comprises a micro LED array that forms a pixel array, such as a 640*480 pixel array. In some embodiments, the length of the micro LED display panel cannot be more than 100, 200, 300, 400 or 500 microns and the width of the micro LED display panel cannot be more than 100, 200, 300, 400 or 500 microns. In some embodiments, the length of the micro LED display panel cannot be more than 1 cm and the width of the micro LED display panel cannot be more than 1 cm. In some embodiments, the length of the micro LED display panel cannot be more than 2 cm and the width of the micro LED display panel cannot be more than 2 cm. In some embodiments, the length of the micro LED display panel cannot be more than 10 cm and the width of the micro LED display panel cannot be more than 10 cm. In some embodiments, the length of the micro LED display panel cannot be more than 20 cm and the width of the micro LED display panel cannot be more than 20 cm. The micro LED display panel also includes an IC back plane. The micro LED display plane includes the micro LED array which includes a plurality of inorganic micro LEDs to show display images. The micro LED array is electrically connected and bonded to the IC back plane. The first ESD protective unit 021, the second ESD protective unit 022, the third ESD protective unit 023, the fourth ESD protective unit 024 and the pixel driver circuit 01 are formed in the IC back plane. In some embodiments, the ESD protective unit is a part of the IC circuit for protecting the IC circuit under the electrostatic discharge state. The ESD protective unit can avoid the current leakage of the IC circuit in the IC back plane.

Herein, the Micro LED can be selected from inorganic LED or organic LED. On the IC back plane, an electrode connected area is electrically connected to the micro LED array and a signal line area is formed around the electrode connected area. The IC back plane acquires signals such as image data from outside via signal lines to control a corresponding micro LED to emit light. The IC back plane generally employs an 8-bit digital to analog converter (DAC). The 8-bit DAC has 256 levels of manifestations, and each level corresponds to one gray level, that is, the 8-bit DAC may provide 256 different gray levels. Since any one of the 256 gray levels may be applied on the micro LED, a gray level ranging from 0 to 255 may be displayed by one pixel. Optionally, a brightness value of the micro LED can be controlled by voltage amplitudes or current amplitudes of the signals acquired by the IC back plane, while the gray levels can be shown by time intervals, e.g., pulse widths, of the signals.

It is understood by those skilled in the art that, the micro display panel is not limited by the structure mentioned above, and may include more or less components than those as illustrated, or some components may be combined, or a different component may be utilized.

It is understood by those skilled in the art that, all or part of the steps for implementing the foregoing embodiments may be implemented by hardware, or may be implemented by a program which instructs related hardware. The program may be stored in a flash memory, in a conventional computer device, in a central processing module, in a adjustment module, etc.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-5 combined or otherwise re-arranged in various other embodiments.

Although the detailed description contains many specifics, these should not be construed as limiting the scope of the invention but merely as illustrating different examples and aspects of the invention. It should be appreciated that the scope of the invention includes other embodiments not discussed in detail above. For example, the approaches described above can be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present invention can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present invention can be incorporated in software and/or firmware for controlling the hardware of a processing system, and for enabling a processing system to interact with other mechanisms utilizing the results of the present invention. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the invention and the various embodiments.

1. An electrostatic discharge (ESD) protection system of a micro device, comprising:
a pixel driver circuit, electrically connected to at least one micro LED pixel for controlling turning-on or off of the micro LED pixel, wherein, the micro LED pixel is electrically connected to a second level voltage; and
a first ESD protective unit, electrically connected to a first level voltage and the second level voltage.

2. The ESD protection system of the micro device according to claim 1, wherein a cathode of the micro LED pixel is connected to the second level voltage.

3. The ESD protection system of the micro device according to claim 2, wherein, the first ESD protective unit is connected to a fourth level voltage and the second level voltage.

4. The ESD protection system of the micro device according to claim 3, wherein the fourth level voltage is higher than the second level voltage and the first level voltage is higher than the fourth level voltage.

5. The ESD protection system of the micro device according to claim 4, wherein the first level voltage is a positive voltage, the fourth level voltage is Zero, and the second level voltage is a negative voltage.

6. The ESD protection system of the micro device according to claim 1, wherein, the first ESD protective unit comprises a power ESD clamp.

7. The ESD protection system of the micro device according to claim 3, wherein the first ESD protective unit comprises a MOS transistor, a gate of the first ESD protective unit is connected to a source of the first ESD protective unit and the second level voltage, the drain of the first ESD protective unit is connected to the first level voltage, and, the first ESD protective unit has a parasitic on the MOS transistor.

8. (canceled)

9. The ESD protection system of the micro device according to claim 3, wherein the first ESD protective unit comprises:
a first type semiconductor substrate;
a first type well region, formed in the first type semiconductor substrate;
a second type well, formed around the first type well region;
a second type deep well, formed at bottom of the second type well and at bottom of the first type well region;
a second type source, formed in the first type well region;
a second type drain, formed in the first type well region;
a first implanted region, formed beside the second type drain;
a gate, formed on the first type well region between the second type source and the second type drain and connected to the second type source and the first implanted region; and,
a second implanted region, formed beside the second type well.

10. The ESD protection system of the micro device according to claim 9, wherein the first type is P type and the second type is N type, the first implanted region is a first P+ implanted region, and the second implanted region is a second P+ implanted region.

11. The ESD protection system of the micro device according to claim 9, wherein the second type well and the second type drain are connected to the first level voltage, the second implanted region is connected to the fourth level voltage, and the first implanted region, the second type source and the gate are connected to the second level voltage.

12-13. (canceled)

14. The ESD protection system of the micro device according to claim 1, wherein the micro pixel driver circuit is connected to the first level voltage and the micro LED pixel.

15. The ESD protection system of the micro device according to claim 1, wherein the system further comprises a second ESD protective unit, and the second ESD protective unit is connected to the first level voltage and a fourth level voltage.

16. The ESD protection system of a micro device according to claim 15, wherein the first ESD protective unit and the second ESD protective unit are formed in a semiconductor substrate.

17. The ESD protection system of the micro device according to claim 15, wherein the second ESD protective unit comprises multiple second ESD sub clamps, wherein a first end of each of the second ESD sub clamps is connected to the first level voltage and the pixel driver circuit, a second end of the each of the second ESD sub clamps is connected to the fourth level voltage, and, the second ESD sub clamps are connected to each other in parallel.

18-19. (canceled)

20. The ESD protection system of the micro device according to claim 1, wherein the system further comprises a third ESD protective unit, a first end of the third ESD protective unit is connected to the first level voltage and a second end of the third ESD protective unit is connected to a fourth level voltage.

21. The ESD protection system of the micro device according to claim 20, wherein the third ESD protective unit is connected to an Input/Output circuit.

22. The ESD protection system of the micro device according to claim 20, wherein the third ESD protective unit comprises at least two third ESD sub clamps, and, the third ESD sub clamps are connected to each other in series.

23. The ESD protection system of the micro device according to claim 1, wherein a first end of the micro pixel driver circuit is connected to a third level voltage, and a second end of the micro pixel driver circuit is connected to the micro LED pixel.

24. The ESD protection system of the micro device according to claim 23, wherein the system further comprises a fourth ESD protective unit, and, a first end of the fourth ESD protective unit is connected to a third level voltage and a second end of the fourth ESD protective unit is connected to a fourth level voltage.

25. The ESD protection system of the micro device according to claim 24, wherein the fourth level voltage is lower than the third level voltage.

26. (canceled)
